(19) United States
(12) Patent Application Publication
(10) Pub. No.: US 2006/0244340 A1
(43) Pub. Date: Nov. 2, 2006

(54) High power ultrasonic transducer

(76) Inventors: Kaustubh P. Marathe, Jamestown, NY (US); Zhaoxia Cao, Jamestown, NY (US); Brian D. Bernhardt, Jamestown, NY (US); Benjaman R. Johnson, Jamestown, NY (US); Gregory E. Phaneuf, Lakewood, NY (US); William L. Puskas, New London, NH (US)

Correspondence Address: Mark G. Lappin;Greenberg Trauring, LLP, One International Place, Boston, MA, 02110, US

(21) Appl. No.: 11/115,768

(22) Filed: Apr. 27, 2005

(51) Int. Cl. H01L 41/00; G01N 29/00

(52) U.S. Cl. 310/321; 73/632

(57) ABSTRACT

A transducer includes a resonator assembly having a first surface and a second surface on opposite sides thereof, a front mass having a surface adjacent to the first surface of the resonator assembly, a back mass having a surface adjacent to the second surface of the resonator assembly, and a compression assembly mounted on the front mass and the back mass. The compression assembly is adapted to effect compression across the resonator assembly. At least one of the surfaces of the front mass and the back mass adjacent to the resonator assembly and first and second surfaces of the resonator assembly is curved when the compression assembly is not in the compression state, and when the compression assembly effects the compression across the resonator assembly, the transducer has a substantially constant pressure across the surfaces of the resonator assembly.

### FIELD OF THE INVENTION

The present invention relates to ultrasonic systems, and more particularly, to systems for generating high power ultrasonic sound energy and introducing the ultrasonic sound energy into fluid media for the purpose of cleaning and/or liquid processing.

### BACKGROUND OF THE INVENTION

For years, ultrasonic energy has been used in manufacturing and processing plants to clean and/or otherwise process objects within liquids. It is well known that objects may be efficiently cleaned by immersion in an aqueous solution and subsequent application of ultrasonic energy to the solution. Prior art ultrasound transducers include resonator components that are typically constructed of materials such as piezoelectrics, ceramics, or magnetostrictives (aluminum and iron alloys or nickel and iron alloys). These resonator components spatially oscillate at the frequency of an applied stimulating signal. The transducers are mechanically coupled to a tank containing a liquid that is formulated to clean or process the object of interest. The amount of liquid is adjusted to partially or completely cover the object in the tank, depending upon the particular application. When the transducers are stimulated to spatially oscillate, they transmit ultrasound into the liquid, and hence to the object. The interaction between the ultrasound-energized liquid and the object create the desired cleaning or processing action.

As shown in FIGS. 1A-1C, one type of prior art ultrasound transducer includes one or more resonator components compressed between a front plate and a back plate, with the compression typically established by a nut and bolt assembly, with the bolt extending from the back plate, through the back plate, resonator component(s) and the front plate and terminated by the nut adjacent to the front plate or terminated by a threaded bore in the front plate, which functions as a nut. FIG. 1A shows a cross-sectional exploded view when the transducer is not in a compression state and FIG. 1B shows a cross-sectional view of the transducer when the transducer is under a compression state. FIG. 1C schematically illustrates a chart of pressure on the surfaces of the resonator versus the radius R of the resonator. As shown in FIG. 1C, in these types of ultrasound transducers, the pressure applied by the front and back plates to the resonator is not evenly distributed across the surfaces of the resonator adjacent the plates, with higher pressure at regions close to the center of the discs and lower pressure at the peripheral regions of the discs. The non-evenly distributed pressure may reduce the reliability, capability, and lifespan of the transducer.

### SUMMARY OF THE INVENTION

In general, one or more ultrasonic generators drive one or more ultrasonic transducers or arrays of transducers, in accordance with the embodiments described herein, coupled to a liquid to clean and/or process a part or parts. The liquid is preferably contained within a tank, and the one or more ultrasonic transducers mount on or within the tank to impart ultrasound into the liquid.

According to one aspect of the present invention, the transducer includes a resonator assembly having a first surface and a second surface on opposite sides thereof, a front mass having a surface adjacent to the first surface of the resonator assembly, a back mass having a surface adjacent to the second surface of the resonator assembly, and a compression assembly mounted on the front mass and the back mass. The compression assembly is adapted to fasten the front and back masses, biasing those masses toward each other and thereby effecting compression across the resonator assembly. In one preferred form, at least one of the surfaces of the front mass and the back mass adjacent the resonator is curved when the compression assembly is not in the compression state, and when the compression assembly effects the compression across the resonator assembly, the transducer has a substantially constant pressure across the surfaces of the resonator assembly. In an alternative form, at least one of the first and second surfaces of the resonator assembly is curved when the compression assembly is not in the compression state, and when the compression assembly effects the compression across the resonator assembly, the transducer has a substantially constant pressure across the first and second surfaces of the resonator assembly.

According to one preferred embodiment, the resonator assembly includes at least one resonator. According to another preferred embodiment, the resonator assembly includes two resonators placed one on top of the other.

The “resonator or resonator assembly” refers to the central components compressed between the front mass and the back mass in a sandwich type transducer. These central components typically include one or more driven elements and one or more electrodes. In some embodiments the central components may also include one or more insulators, one or more heatsinking elements or electrodes that also can be used as heatsinking elements.

According to another preferred embodiment, the compression assembly is mounted on central regions of the front and back masses. In one preferred form, the compression assembly includes a bias bolt and nut assembly, and the front mass, the resonator assembly, and the back mass define a bore extending along a central axis of the front mass, the resonator assembly, and the back mass for receiving the bolt. In some embodiments, the bolt is adapted to pass through the central bore of the stacked back mass, resonator assembly and front mass, and the nut is a discrete element, which is screwed onto a lead end of the bias bolt. In other embodiments, the bore defined in the front mass includes threads on an inner surface of said bores, and the lead end of the bias bolt is screwed into the threaded bore in the front mass, so that the front mass acts as the “nut”. The bolt can extend from the front mass to a nut in or adjacent to the back mass or it can extend from the back mass to a nut adjacent to or within the front mass. The bias bolt and nut adjustably engage the back mass and the front mass so as to compress the one or more resonators between the back mass and the front mass.

With the compression assembly mounted on the central regions of the front and back masses, the at least one curved surface is preferably concave-shaped, such that, in assembly, as the compression assembly is tightened to effect compression across the resonator assembly, the peripheral region of the concave-shaped element physically interacts first with surface of the opposing element, and as the compression assembly is tightened to establish desired compression on the resonator assembly, the masses establish a pressure on the resonator assembly that is substantially uniform across the adjacent surfaces of the masses and resonator assembly.

In one preferred embodiment, the surface of the front mass adjacent the resonator assembly and the surface of the back mass adjacent the resonator assembly are concave-shaped. In another preferred embodiment, the first and second surfaces of the resonator assembly are concave-shaped. Other combinations of concave surfaces may be used as well, so that upon compression a substantially constant pressure is achieved across the resonator surface(s).

According to another aspect of the present invention, the compression assembly is mounted on peripheral regions of the front mass and the back mass. In one preferred form, the compression assembly includes at least two bolt and nut assemblies, and the front mass and the back mass define at least two bores at peripheral regions extending along axes parallel to a central axis of the front mass and the back mass for receiving the at least two bolts. The nut can be a discrete element that is adapted to be screwed on a lead end of a corresponding bolt, or alternatively, the bore in the front mass includes threads on inner surface for engaging the threads on the lead end of the bolt, such that the front mass functions as the “nut”. The bias bolts adjustably engage the back mass and the front mass so as to compress the one or more resonators between the back mass and the front mass.

With the compression assembly mounted on peripheral regions of the front and back masses, the at least one curved surface is preferably convex-shaped, such that, in assembly, as the compression assembly is tightened to effect compression across the resonator assembly, the central region of the convex-shaped element physically interacts first with surface of the opposing element, and as the compression assembly is tightened to establish desired compression on the resonator assembly, the masses establish a pressure on the resonator assembly that is substantially uniform across the adjacent surfaces of the masses and resonator assembly.

According to one preferred embodiment, the surface of the front mass adjacent the resonator assembly and the surface of the back mass adjacent the resonator assembly are convex-shaped. According to another preferred embodiment, the first and second surfaces of the resonator assembly are convex-shaped. Other combinations of convex surfaces may be used as well, so that upon compression a substantially constant pressure is achieved across the resonator surface(s).

The transducer may further include insulators disposed between the bolt and the resonator assembly, and electrodes connected to the resonator assembly.

According to a further aspect of the present invention, the sandwich type ultrasonic transducer preferably has a low-density back mass (i.e., aluminum, magnesium, etc.) and is used to produce a device with an especially wide bandwidth. This large bandwidth allows effective sweeping over a dramatically larger range of frequencies. A low-density back mass provides a larger surface area compared to that of a prior art steel back mass of the same acoustic length. This increased surface area also allows higher heat dissipation per transducer that in turn allows a higher overall power output at the primary as well as overtone frequencies.

According yet another aspect of the present invention, the resonators are made from ceramic, preferably non-silvered piezoelectric ceramic. Elimination of the oft-applied silver to the faces of the piezoelectric ceramic is accomplished through a lapping process that ensures extreme flatness of the piezoelectric ceramics. These flat non-silvered surfaces optimize utilization for high power applications. A transducer characterized by an especially high bandwidth may or may not contain non-silvered piezoelectric resonators. An example of another improvement is the incorporation of multiple concentric ceramic piezoelectric elements in place of the solid ceramic piezoelectric discs often used. In one application the size and geometry of these concentric cylindrical shells are tailored to ensure that the radial resonant frequencies of the resonators do coincide with that of the transducer assembly for maximized output at that frequency. In another application these concentric rings are tailored to ensure that the radial resonant frequencies of the resonators do not coincide with that of the transducer assembly to minimize strain at those frequencies. These resonators can be silvered or lapped free of silver.

According to another aspect of the present invention, another improvement of the transducer is a deviation from cylindrical symmetry on any of the components for the reason of yielding a device of extreme bandwidth as well as the manipulation/elimination of radial resonant frequencies. An example of this deviation from cylindrical symmetry includes slots on the sides of the front mass or elliptical masses. If properly implemented, deviation from cylindrical symmetry, including the addition of flats or slots on the sides of the high power ultrasonic transducer front mass, can result in a device with exceptionally large bandwidth. In a similar way to concentric ceramics, it can also result in a transducer having radial resonance frequencies that are tailored with respect to the rest of the frequency spectrum, specifically the longitudinal resonance. Large bandwidth allows effective sweeping over a dramatically larger range of frequencies. This transducer is designed specifically to have as flat an impedance verses frequency curve as possible in the region of said transducer's resonance, or any of its overtones. This design feature is intended to maximize the benefits obtained from the sweeping of frequencies within some bandwidth about some center frequency. Sweeping frequency, the most primitive type of frequency modulation (FM), has had a major impact on the ultrasonic cleaning industry over the last twelve years. When done correctly, it improves the performance of an ultrasonic cleaner and generally reduces the damage to delicate parts caused by constant frequency ultrasonics. Introducing a change in the frequency, as a function of time, of an ultrasonic array can effect what happens in a tank in a number of ways. This includes how energy is transferred to the fluid, how efficiently that sound energy is converted into cavitational energy, and how energy is transferred to a part. Once a certain amount of ultrasonic energy has been transferred to the fluid medium one must examine how much of that energy is expressed in the form of cavitation. An effective way of representing this is with a mathematical tool known as the acoustic interaction cross-section. The acoustic interaction cross-section is given by the ratio of the time-averaged power subtracted from an incident acoustic wave as a result of the presence of a bubble, of some size R, to the intensity of the incident acoustic wave. Simply, this is the amount of energy subtracted from an incident acoustic wave by a bubble driven into oscillation. This energy is subsequently re-radiated by the bubble via pulsation or implosion and affects much of the cleaning accomplished by ultrasonics. As its name suggests, acoustic interaction cross-section has the units of area, i.e., square meters.

### BRIEF DESCRIPTION OF DRAWINGS

The foregoing and other objects of this invention, the various features thereof, as well as the invention itself, may be more fully understood from the following description, when read together with the accompanying drawings in which:

FIG. 1A shows a cross-sectional exploded view of a prior art transducer;

FIG. 1B shows a cross-sectional view of the prior art transducer in FIG. 1A when the transducer is under a compression state;

FIG. 1C schematically shows a chart of pressure on the surface of a resonator versus the radius of the resonator of the prior art transducer in FIGS. 1A and 1B;

FIG. 2 shows a perspective view of a transducer according to one preferred embodiment of the present invention;

FIG. 3 shows a top view of the transducer in FIG. 2;

FIG. 4A shows a cross-sectional exploded view of a transducer according to one preferred embodiment of the present invention;

FIG. 4B shows a cross-sectional view of the transducer in FIG. 4A when the transducer is under a compression state;

FIG. 4C schematically shows a chart of pressure on the surface of a resonator versus the radius of the resonator of the transducer in FIGS. 4A and 4B;

FIG. 5A shows a cross-sectional exploded view of a transducer according to another preferred embodiment of the present invention;

FIG. 5B shows a cross-sectional view of the transducer in FIG. 5A when the transducer is under a compression state;

FIG. 5C schematically shows a chart of pressure on the surface of a resonator versus the radius of the resonator of the transducer in FIGS. 5A and 5B;

FIG. 6A shows a cross-sectional exploded view of a transducer according to another preferred embodiment of the present invention;

FIG. 6B shows a cross-sectional view of the transducer in FIG. 6A when the transducer is under a compression state;

FIG. 6C schematically shows a chart of pressure on the surface of a resonator versus the radius of the resonator of the transducer in FIGS. 6A and 5B;

FIG. 7A shows a cross-sectional exploded view of a transducer according to another preferred embodiment of the present invention;

FIG. 7B shows a cross-sectional view of the transducer in FIG. 7A when the transducer is under a compression state;

FIG. 7C schematically shows a chart of pressure on the surface of a resonator versus the radius of the resonator of the transducer in FIGS. 7A and 7B;

FIG. 8A shows a cross-sectional exploded view of a transducer according to another preferred embodiment of the present invention;

FIG. 8B shows a cross-sectional view of the transducer in FIG. 8A when the transducer is under a compression state;

FIG. 8C schematically shows a chart of pressure on the surface of a resonator versus the radius of the resonator of the transducer in FIGS. 8A and 8B;

FIG. 9 schematically shows a side view of a front mass and a back mass of a transducer according to one preferred embodiment of the present invention;

FIG. 10 schematically shows a side view of a front mass and a back mass of a transducer according to another preferred embodiment of the present invention;

FIG. 11 schematically shows a side view of a front mass and a back mass of a transducer according to a further preferred embodiment of the present invention;

FIG. 12A shows a front mass that deviates from cylindrical symmetry by including lateral slots, parallel to the central axis AX;

FIG. 12B shows a front mass that deviates from cylindrical symmetry by including an elliptical cross section in a plane perpendicular to the central axis AX;

FIG. 12C shows a front mass that deviates from cylindrical symmetry by including flat regions along the outer surface of the front mass, running parallel to the central axis AX; and

### DESCRIPTION OF THE PREFERRED EMBODIMENTS

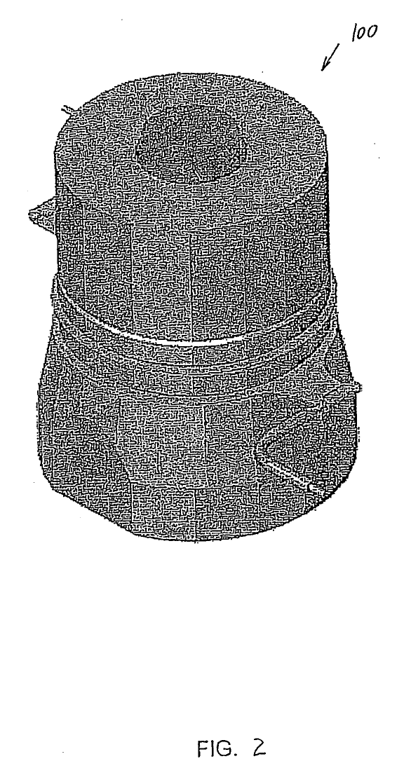

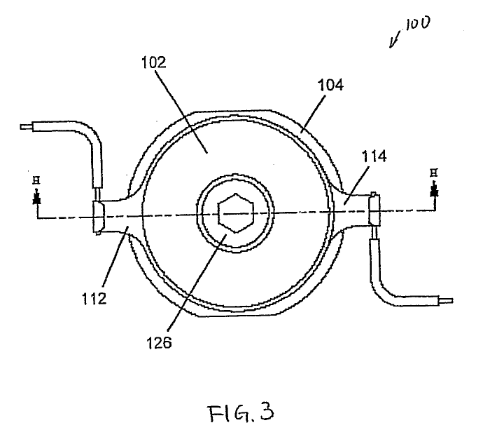

FIG. 2 shows a perspective view of one preferred embodiment of an ultrasonic transducer 100 and FIG. 3 shows a top view of the transducer 100 of FIG. 2. FIGS. 4A and 4B show cross-sectional views (section H-H from FIG. 3) of the transducer 100 of FIG. 2, FIG. 4A depicting an exploded view to show the parts of the transducer 100 and FIG. 4B depicting a cross-sectional view of the transducer 100 when the transducer is under a compressed state. The transducer 100 employs a Langevin architecture, also known in the art as a sandwich transducer. According to one aspect of the invention, the transducer 100 includes a back mass 102, a front mass 104, a resonator assembly including a first ceramic disc resonator 106 and a second ceramic disc resonator 108, and a compression assembly including a central bias bolt 116. The transducer may further include an insulator, which is not shown in the drawings, disposed between the bolt 116 and the disc resonators 106 and 108, and electrodes 112 and 114 (as shown in FIG. 3) connected to the disc resonators 106 and 108. In the embodiment of FIGS. 2, 3, 4A and 4B, the back mass 102, front mass 104, first ceramic disc 106 and second ceramic disc 108 are each characterized by a substantially annular shape extending about a central axis AX, and characterized by an inner radius 118 and an outer radius 120. The inner radius 118 and outer radius 120 are shown in FIG. 4A for the back mass 102 only. Each of the other components (the front mass 104 and the ceramic discs 106 and 108 is characterized by a corresponding inner radius and outer radius, which may or may not be the same as the other components in the transducer 100. The inner radius 118 of the back mass 102 undergoes an abrupt change near the back end, forming a shelf 124 in the inner bore.

In the embodiment shown in FIGS. 4A and 4B, the bore of the front mass 104, characterized by the inner radius of the front mass 104, does not extend completely through the front mass 104 along the axis AX. Other embodiments may include an inner bore of the front mass 104 that extends completely through the front mass 104. The front mass 104 further includes threads on the walls of the inner bore. In one preferred embodiment, the threads are machined into the inner bore, although other techniques known in the art may also be used to create threads in the inner bore.

The back mass 102, front mass 104, first ceramic disc 106 and second ceramic disc 108 are stacked so as to be adjacent and disposed along the common central axis AX, as shown in FIGS. 4A and 4B. The first ceramic disc 106 and the second ceramic disc 108 are “sandwiched” between the back mass 102 and the front mass 104. The bias bolt 116 is preferably symmetrically disposed about the common axis AX, and includes a first end 126 and a second end 128. The outer radius near first end 126 is characterized by an abrupt change, forming a shelf 130. The second end 128 includes threads along the outer surface for mating with the threads on the walls of the inner bore of the front mass 104. The transducer 100 is assembled by passing the bias bolt 116 through the bore of the back mass 102, the bore of the first ceramic disc 106, the bore of the second ceramic disc 108, and into the bore of the front mass 104. The threads on the bias bolt 116 engage the threads in the bore of the front mass 104. As the bias bolt 116 is tightened, the bias bolt 116 is drawn into the bore of the front mass 104, and the shelf 130 on the bias bolt 116 contacts the shelf 124 on the back mass 102, thereby applying a force to the back mass 102 along the axis AX toward the front mass 104. Further tightening the bias bolt 116 compresses the first ceramic disc 106 and the second ceramic disc 108 between the front mass 104 and the back mass 102. The bias bolt 116 can be tightened or loosened to adjust the amount of compression on the ceramic discs 106 and 108.

The electrodes connected to the discs 106 and 108 provide input ports to the resonators for a stimulating signal from an ultrasonic signal generator. In some embodiments of the transducer 100, the resonators may receive the stimulating signal via an electrically conducting front mass and/or an electrically conducting back mass, instead of or in addition to the electrodes. The resonator components within the transducer 100 spatially oscillate in one or more modes associated with the frequency of the applied stimulating signal. The transducer 100 transmits the spatial oscillations via the front mass as ultrasound, to (for example) a tank that contains a cleaning solution and an object to be cleaned.

According to one aspect of the present invention, prior to assembly with the discs under compression, at least one of the adjacent surfaces of the masses and the ceramic discs is curved, for example, having a concave shape extending about the central axis AX. As shown in FIG. 4A, in one preferred form, a bottom surface 402 of the back mass 102 and a top surface 404 of the front mass 104 are concave-shaped. In a preferred embodiment, where the diameter of elements 102, 106 and 108 is 1.50 inches, the center of the concave surface is preferably about 0.0002 inches to 0.001 inches deep.

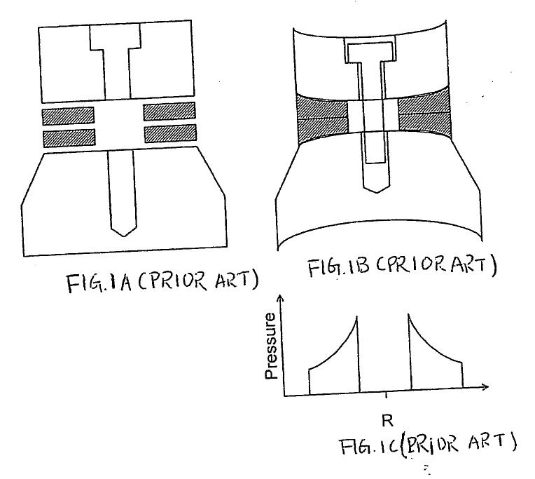

In use, when the central bias bolt 116 is tightened, the opposing surfaces 402 and 404 come together, compressing first the peripheral portions of the concave surfaces 402 and 404, and then the entire surfaces, when the bolt is fully tightened. The front and back masses 104 and 102 establish a desired compression of the discs 106 and 108, such that the pressure on the adjacent surfaces of the discs 106 and 108 (including a top surface 406 and a bottom surface 408) exerted by the front and back masses 104 and 102 is substantially evenly distributed across the surfaces 406 and 408 of the discs and the respective adjacent surfaces of the front and back masses. FIG. 4C schematically shows a chart of pressure across the surfaces 406 or 408 versus the radius R of the discs 106 or 108. As seen in FIG. 4C, the pressure on the surfaces 406 or 408 of the discs 106 or 108 is substantially uniform across the entire surface, however, in the prior art device, as shown in FIG. 1C, the pressure at regions close to the center of the discs is much higher than the pressure at the peripheral regions of the discs.

With the evenly distributed compressing pressure on the discs, at a given power, the operational reliability of the transducer is improved because lower localized compressive stress is seen by the inside diameter of the internal components during the compression half cycle and lower localized tensile stress is seen by the outside diameter of the internal components during the expansion half cycle of the transducer. These lower extremes in localized stresses significantly reduce fatigue related reliability issues. Also, as the localized pressure is substantially even across the adjacent surfaces of the resonator or resonators and other internal components, it is thereby possible to operate the transducer at higher powers because the maximum peak excursion capability is significantly higher, where the maximum peak excursion is defined as the difference between the maximum peak expansion half cycle and the maximum peak compression half cycle, and where the maximum peak expansion half cycle is the expansion distance that does not exceed the tensile yield strength of the resonator, resonators, or other internal components in any localized area, and where the maximum peak compressive cycle is the compression distance that does not exceed the compressive yield strength of the resonator, resonators, or other internal components in any localized area.

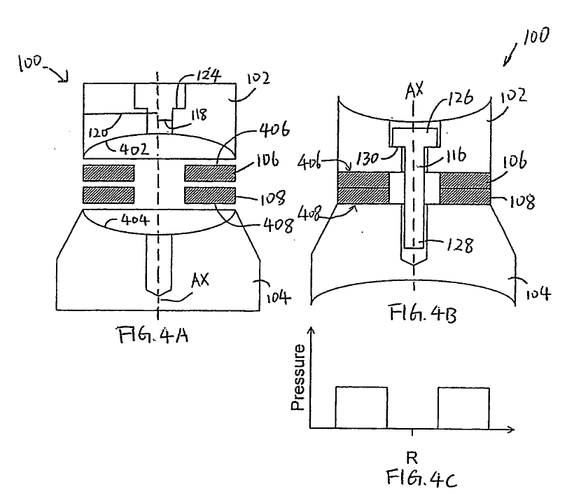

FIGS. 5A and 5B illustrate cross-sectional views of another preferred embodiment, in which the bottom surface 402 of the back mass 102 is concave-shaped and the top surface 404 of the front mass 104 is substantially flat. FIG. 5A depicts an exploded view to show the parts of the transducer 100. FIG. 5B depicts the transducer 100 under compression. FIG. 5C schematically shows a chart of pressure across the surfaces 406 or 408 of the ceramic discs versus the radius R of the discs 106 or 108. As seen in FIG. 5C, the pressure on the surfaces 406 or 408 of the discs 106 or 108 is substantially uniform across the entire surface.

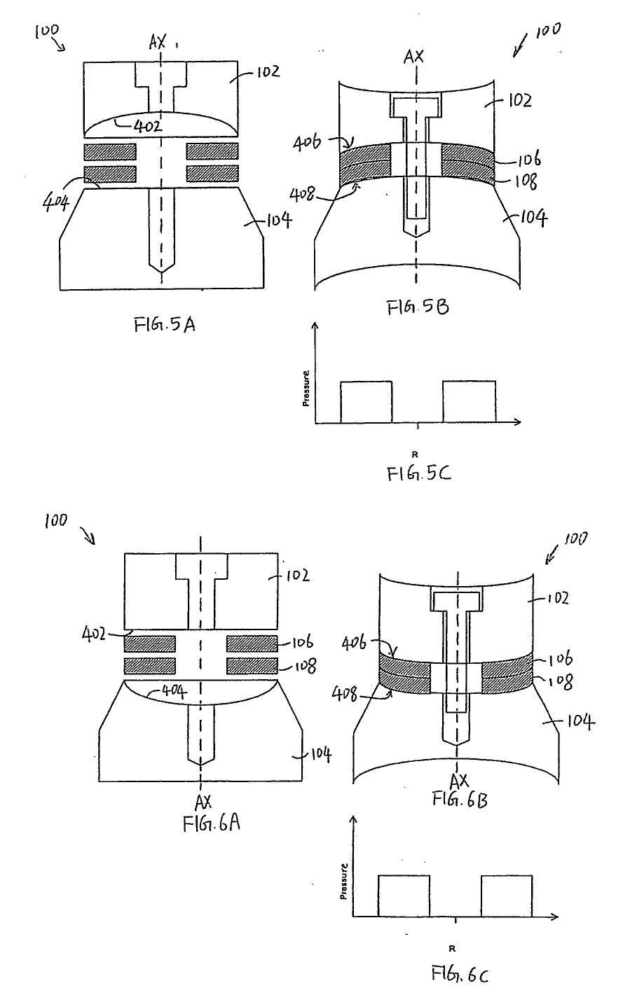

FIGS. 6A and 6B illustrate cross-sectional views of a further preferred embodiment, in which the top surface 404 of the front mass 104 is concave-shaped and the bottom surface 402 of the front mass 102 is substantially flat. FIG. 6A shows an exploded view to show the parts of the transducer 100. FIG. 6B depicts the transducer 100 under compression. FIG. 6C schematically shows a chart of pressure across the surfaces 406 or 408 of the ceramic discs versus the radius R of the discs 106 or 108. As seen in FIG. 6C, the pressure on the surfaces 406 or 408 of the discs 106 or 108 is substantially uniform across the entire surface.

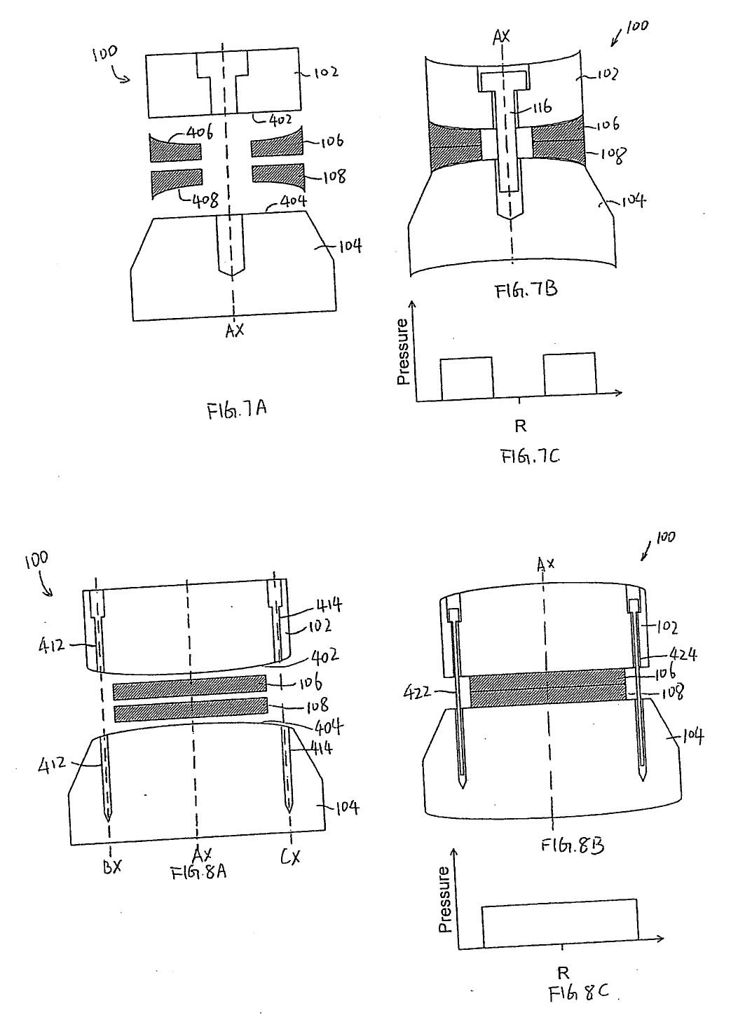

FIG. 7A illustrates a cross-sectional exploded view of another preferred embodiment, in which both of the top surface 406 of the first ceramic disc 106 and the bottom surface 408 of the second ceramic disc 108 are concaved-shaped, and the bottom surface 402 of the back mass 102 and the top surface 404 of the front mass 104 are substantially flat. A person skilled in the art should appreciate that the transducer 100 may be implemented, in alternative forms which are not shown in the drawings, with only one of the top surface 406 and the bottom surface 408 of the discs is concave shaped. FIG. 7B shows a cross-sectional view of the transducer 100 when the central bolt 116 is tightened and the ceramic discs 106 and 108 are under compression. FIG. 7C schematically shows a chart of pressure across the surfaces 406 or 408 of the ceramic discs versus the radius R of the discs 106 or 108. As shown in FIG. 7C, the pressure on the surfaces 406 or 408 of the discs 106 or 108 is substantially uniform across the entire surface.

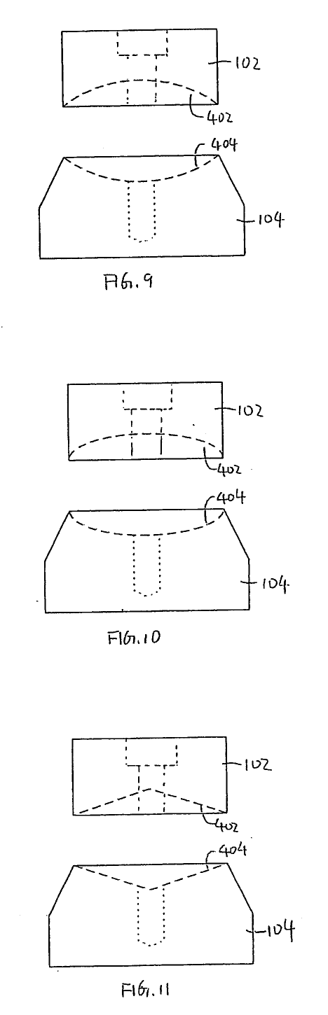

FIG. 8A illustrates a cross-sectional exploded view of a further preferred embodiment of the present invention. As shown in FIG. 8A, the transducer 100 includes a back mass 102, a front mass 104, a first ceramic disc 106 and a second ceramic disc 108, which are stacked so as to be adjacent and disposed along a common central axis AX. The first ceramic disc 106 and the second ceramic disc 108 are “sandwiched” between the back mass 102 and the front mass 104 and have relatively smaller diameter than the back mass 102 and the front mass 104. The front mass 104 and the back mass 102 define at least two elongated bores 412 and 414 at peripheral regions of the front mass 104 and the back mass 102. The elongated bores 412 and 414 extend along axes BX and CX, which are parallel to the central axis AX, and each include a first section defined in the back mass 102 and a second section defined in the front mass 104. The transducer 100 further includes at least two bias bolts 422 and 424 to be inserted into the elongated bores 412 and 414 to fasten back mass 102 and the front mass 104, as shown in FIG. 8B. The elongated bores 412 and 414 and the bias bolts 422 and 424 have a similar structure as the central bore and the central bias bolt 116 of the embodiments shown in FIGS. 4A-7C. Each of the bolts 422 and 424 includes a first end and a second end, and the second ends of the bolts include threads on the outer surface for mating with threads on the inner surfaces of the second sections of the bores 412 and 414, which are defined in the front mass 104. FIGS. 8A and 8B show only two bolts and two bores defined in the front and back masses. The transducer 100 preferably include three, or four, or more bolts, and the front and back masses define a corresponding number of bores at peripheral regions of the front and back masses for fastening the front and back masses.

As shown in FIG. 8A, prior to assembly with the discs under compression, both of the bottom surface 402 of the back mass 102 and the top surface 404 of the front mass 104 are preferably convex-shaped, extending about the central axis AX. A person skilled in the art should appreciate that the transducer 100 may be implemented, in other alternative forms which are not shown in the drawings, for example, with only one of the bottom surface 402 and the top surface 404 convex-shaped or with the top surface 406 of the first disc 106 and/or the bottom surface 408 of the second disc 108 convex-shaped.

The transducer 100 is assembled by passing the bias bolts 422 and 424 through the first sections of the bores in the back mass 102, and into the second sections of the bores 412 and 414 of the front mass 104. The threads on lead ends of the bias bolts 422 and 424 engage the threads in the bores 412 and 414 of the front mass 104. As the bias bolts 422 and 424 are tightened, the bias bolts 422 and 424 are drawn into the bores of the front mass 104, thereby applying a compressing force to the back mass 102 along the axes BX and CX toward the front mass 104. Further tightening the bias bolts 422 and 424 compress the first ceramic disc 106 and the second ceramic disc 108 between the front mass 104 and the back mass 102. The bias bolts 422 and 424 can be tightened or loosened to adjust the amount of compression on the ceramic discs 106 and 108.

When the bias bolts 422 and 424 are tightened, the opposing surfaces 402 and 404 come together, compressing first the central regions of the convex surfaces 402 and 404, and then the entire surfaces, when the bolts are fully tightened. The front and back masses 104 and 102 establish a substantially uniform compression against the discs 106 and 108, such that the pressure on the adjacent surfaces of the discs 106 and 108 (including a top surface 406 and a bottom surface 408) exerted by the front and back masses 104 and 102 is substantially evenly distributed across the entire surfaces 406 and 408 of the discs. FIG. 8C schematically shows a chart of pressure across the surfaces 406 or 408 of the ceramic discs versus the radius R of the discs 106 or 108. As shown in FIG. 7C, the pressure on the surfaces 406 or 408 of the discs 106 or 108 is substantially uniform across the entire surface.

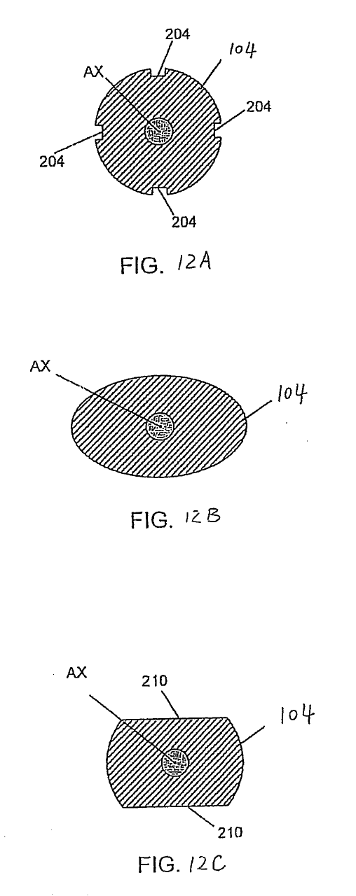

The concave-shaped or convex-shaped surfaces of the masses 102 and 104 and ceramic discs 106 and 108 in the embodiments shown in FIGS. 2-8C can be substantially spherical, conical, or embodying other suitable shapes. FIGS. 9-11 schematically show various exemplary embodiments of the shape of the concave surfaces. A person skilled in the art should appreciate that the shape of the concave or convex surfaces should not be limited to the embodiments shown in the drawings. In FIG. 9, the opposing top surface 404 and bottom surface 402 are substantially spherical-shaped. FIG. 10 illustrates an “ideal” curved shape of the opposing top surface 404 and bottom surface 402, which may be designed with computer analysis such that the curved surfaces 402 and 404 provide substantially evenly distributed pressure across the adjacent disc surfaces when the bolt is fully tightened and the front and back masses are under compression. In FIG. 11, the opposing top surface 404 and bottom surface 402 are substantially conical-shaped. A person skilled in the art should appreciate that other similar arrangements, although not depicted in the drawings, also can be used without departing from the concept of the present disclosure.

In the above-illustrated exemplary embodiments, the lead end of the bias bolt(s) is screwed into a threaded bore in the front mass for tightening the transducer assembly, so that the front mass acts as a “nut”. In alternative forms, the bore may extend through the front mass and a nut, which is a discrete element, is screwed onto the lead end of the bias bolt to tighten the transducer assembly. A person skilled in the art should also appreciate that other compression assemblies for tightening and compressing the front and back masses can be used to replace the bolt and nut assembly.

According to a further aspect of the present invention, the back mass 102 is fabricated from a low-density material (with respect to prior art back mass components) such as aluminum, magnesium, beryllium, titanium, or other similar materials known in the art, including alloys and other mixed composition materials. As used herein, the term “low density material” describes a material with a density of less than 6.0 grams per cubic centimeter (g/cc). In one preferred embodiment, the back mass 102 is made of type 7075-T651 aluminum, although other similar materials may also be used. In a preferred embodiment, the front mass 104 is made of type 2024 aluminum, although other similar materials may also be used. The back mass 102 and front mass 104 being made from different materials contributes to the ultrabroad bandwidth of the transducer 100. A low density back mass 104 results in a physically longer back mass, or a larger surface area as compared to a higher density back mass of the same acoustic length. The increased length (or larger surface area) further contributes to the multiple center frequencies of operation, and the ultrabroad bandwidth at each of the center frequencies. The disc resonators 106 and 108 are fabricated from a ceramic material that has been polarized via techniques well know in the art to imbue a piezoelectric effect. In other embodiments, the resonators may include other piezoelectric materials known in the art, such as natural piezoelectrics (e.g., quartz) or magnetorestrictives. Further, although the embodiment of FIGS. 2-8C includes two disc resonators, other embodiments of the transducer 100 may include a single resonator, or multiple (i.e., more than two) resonators.

FIGS. 2 and 3 show that the transducer is cylindrically symmetrical about the central axis AX. Other embodiments of the transducer 100 may include transducer components that deviate from cylindrical symmetry, as shown for example in FIGS. 12A, 12B and 12C. The front mass 104 shown in cross section (in a plane perpendicular to the central axis AX) in FIG. 12A deviates from cylindrical symmetry by including lateral slots 204, each extending along axis parallel to the central axis AX, on the front mass 104. Another exemplary deviation from cylindrical symmetry is a front mass 104 with an elliptical cross section in a plane perpendicular to the central axis AX, as shown in FIG. 12B. A further exemplary deviation from cylindrical symmetry is a front mass 104 with flat regions 210 along the outer surface of the front mass, extending parallel to the central axis AX, as shown in FIG. 12C. In these exemplary embodiments, the back mass 102 and the ceramic discs 106 and 108, correspondingly, may embody the same or a similar shape as the front mass 104. Such deviations from cylindrical symmetry exemplified by the embodiments of FIGS. 12A, 12B and 12C result in transducer devices that have empirically demonstrated extremely wide bandwidth, and allow tailoring, manipulation or elimination of radial resonant frequencies. A large transducer bandwidth allows effective sweeping over a dramatically wide range of frequencies. The transducer described herein provides a substantially flat impedance versus frequency curve in the region of the transducer's resonance, or any of its overtones. This feature is intended to maximize the benefits obtained from the sweeping of frequencies within some bandwidth about some center frequency.

The transducer 100 can be operated at a dedicated single frequency, or it can be excited at multiple frequencies, i.e., at the transducer fundamental frequency and/or any of its higher frequency overtones. The size and geometry of the ceramic disc resonators 106 and 108 can be tailored to ensure that the radial resonant frequencies of the resonators coincide with that of the transducer assembly for maximized output at that frequency. In yet another embodiment, the size and geometry of the resonators can be tailored to ensure that the radial resonant frequencies of the resonators do not coincide with that of the transducer assembly, in order to minimize strain on the transducer at those frequencies.

While the above-described embodiments establish a substantially uniform pressure across the resonator surface(s), the desired pressure profiles (as a function of radius about the central axis) may be achieved by changing the geometry of the curved surface(s).

The invention may be embodied in other specific forms without departing from the spirit or essential characteristics thereof. The present embodiments are therefore to be considered in respects as illustrative and not restrictive, the scope of the invention being indicated by the appended claims rather than by the foregoing description, and all changes which come within the meaning and range of the equivalency of the claims are therefore intended to be embraced therein.

What is claimed is:

1. An ultrasonic transducer comprising:
a resonator assembly having a first surface and a second surface on opposite sides thereof;
a front mass having a surface adjacent to said first surface of said resonator assembly;
a back mass having a surface adjacent to said second surface of said resonator assembly;
a compression assembly coupling said front mass and back mass, and adapted to effect a compression across said resonator assembly, wherein at least one of said surfaces is curved when said compression assembly is not in said compression state, and wherein said transducer has a desired pressure profile across said surfaces of said resonator assembly when said compression assembly effects said compression across said resonator assembly.

2. An ultrasonic transducer according to claim 1, wherein said pressure profile is characterized by a substantially constant pressure across said surfaces of said resonator assembly.

3. An ultrasonic transducer according to claim 2, wherein said resonator assembly comprises at least one resonator.

4. An ultrasonic transducer according to claim 2, wherein said resonator assembly comprises two resonators placed one on top of the other.

5. An ultrasonic transducer according to claim 2, wherein said compression assembly is mounted on central regions of said front and back masses.

6. An ultrasonic transducer according to claim 2, wherein said compression assembly includes a bias bolt, and the front mass, the resonator assembly, and the back mass define a bore extending along a central axis of the front mass, the resonator assembly, and the back mass for receiving said bolt.

7. An ultrasonic transducer according to claim 5, wherein said at least one curved surface is concave-shaped.

8. An ultrasonic transducer according to claim 7, wherein said concave-shaped surface is substantially spherical-shaped.

9. An ultrasonic transducer according to claim 7, wherein said concave-shaped surface is substantially conical-shaped.

10. An ultrasonic transducer according to claim 5, wherein said surface of said front mass adjacent said resonator assembly and said surface of said back mass adjacent said resonator assembly are concave-shaped.

11. An ultrasonic transducer according to claim 5, wherein said first and second surfaces of said resonator assembly are concave-shaped.

12. An ultrasonic transducer according to claim 2, wherein said compression assembly is mounted on peripheral regions of said front mass and said back mass.

13. An ultrasonic transducer according to claim 12, wherein said compression assembly includes at least two bias bolts, and the front mass and the back mass define at least two bores at peripheral regions of said front mass and said back mass extending along axes parallel to a central axis of the front mass and the back mass for receiving said at least two bolts.

14. An ultrasonic transducer according to claim 12, wherein said at least one curved surface is convex-shaped.

15. An ultrasonic transducer according to claim 14, wherein said convex-shaped surface is substantially spherical-shaped.

16. An ultrasonic transducer according to claim 14, wherein said convex-shaped surface is substantially conical-shaped.

17. An ultrasonic transducer according to claim 12, wherein said surface of said front mass adjacent said resonator assembly and said surface of said back mass adjacent said resonator assembly are convex-shaped.

18. An ultrasonic transducer according to claim 12, wherein said first and second surfaces of said resonator assembly are convex-shaped.

19. An ultrasonic transducer comprising:
a resonator assembly having a first surface and a second surface on opposite sides thereof;
a front mass having a surface adjacent to said first surface of said resonator assembly;
a back mass having a surface adjacent to said second surface of said resonator assembly;
a compression assembly coupling central regions of said front mass and back mass, and adapted to effect a compression across said resonator assembly, wherein at least one of said surfaces is concave-shaped when said compression assembly is not in said compression state, and wherein said transducer has a desired pressure profile across said surfaces of said resonator assembly when said compression assembly effects said compression across said resonator assembly.

20. An ultrasonic transducer according to claim 19, wherein said pressure profile is characterized by a substantially constant pressure across said surfaces of said resonator assembly.

21. An ultrasonic transducer according to claim 20, wherein said resonator assembly comprises at least one resonator.

22. An ultrasonic transducer according to claim 20, wherein said resonator assembly comprises two resonators placed one on top of the other.

23. An ultrasonic transducer according to claim 20, wherein the front mass, the resonator assembly, and the back mass extend about a central axis and define a bore extending along a central axis of the transducer, and wherein said compression assembly includes a bias bolt adapted to be inserted into and secured in said bore.

24. An ultrasonic transducer according to claim 23, wherein said bolt includes threads on an outer surface of a lead end of said bolt and said bore in said front mass includes threads on an inner surface of said bore for engaging said threads on said bolt, and when said compression assembly effects said compression across said resonator assembly, said lead end passes through said back mass and said resonator assembly and is screwed into said bore in said front mass.

25. An ultrasonic transducer according to claim 20, wherein said concave-shaped surface is substantially spherical-shaped.

26. An ultrasonic transducer according to claim 20, wherein said concave-shaped surface is substantially conical-shaped.

27. An ultrasonic transducer according to claim 20, wherein said surface of said front mass adjacent said resonator assembly and said surface of said back mass adjacent said resonator assembly are concave-shaped.

28. An ultrasonic transducer according to claim 20, wherein said first and second surfaces of said resonator assembly are concave-shaped.

29. An ultrasonic transducer comprising:
a resonator assembly having a first surface and a second surface on opposite sides thereof;
a front mass having a surface adjacent to said first surface of said resonator assembly;
a back mass having a surface adjacent to said second surface of said resonator assembly;
a compression assembly coupling peripheral regions of said front mass and back mass, and adapted to effect a compression across said resonator assembly, wherein at least one of said surfaces is convex-shaped when said compression assembly is not in said compression state, and wherein said transducer has a desired pressure profile across said surfaces of said resonator assembly when said compression assembly effects said compression across said resonator assembly.

30. An ultrasonic transducer according to claim 29, wherein said pressure profile is characterized by a substantially constant pressure across said surfaces of said resonator assembly.

31. An ultrasonic transducer according to claim 30, wherein said resonator assembly comprises at least one resonator.

32. An ultrasonic transducer according to claim 30, wherein said resonator assembly comprises two resonators placed one on top of the other.

33. An ultrasonic transducer according to claim 30, wherein the front mass, the resonator assembly, and the back mass extend about a central axis and define at least two bores extending along axes parallel to said central axis, and wherein said compression assembly includes at least two bias bolts adapted to be inserted into and secured in said bores.

34. An ultrasonic transducer according to claim 33, wherein each of said bolts includes threads on an outer surface of a lead end of said bolt and each of said bores in said front mass includes threads on an inner surface of said bore for engaging said threads on said bolt, and when said compression assembly effects said compression across said resonator assembly, said lead end passes through said back mass and said resonator assembly and is secured in said bore of said front mass.

35. An ultrasonic transducer according to claim 30, wherein said convex-shaped surface is substantially spherical-shaped.

36. An ultrasonic transducer according to claim 30, wherein said convex-shaped surface is substantially conical-shaped.

37. An ultrasonic transducer according to claim 30, wherein said surface of said front mass adjacent said resonator assembly and said surface of said back mass adjacent said resonator assembly are convex-shaped.

38. An ultrasonic transducer according to claim 30, wherein said first and second surfaces of said resonator assembly are convex-shaped.
